(19) United States
(12) Patent Application Publication
(10) Pub. No.: US 2026/0144063 A1
(43) Pub. Date: May 21, 2026

(54) Power Semiconductor Device Package

(71) Applicant: Wolfspeed, Inc., Durham, NC (US)

(72) Inventors: Devarajan Balaraman, Apex, NC (US); Daniel Ginn Richter, Raleigh, NC (US)

(21) Appl. No.: 18/952,558

(22) Filed: Nov. 19, 2024

(51) Int. Cl. H01L 23/00; H01L 23/31; H01L 23/373

(52) U.S. Cl. CPC H10W 40/258; H10W 72/01551; H10W 72/075; H10W 72/07533; H10W 72/07553; H10W 72/531; H10W 72/534; H10W 72/5524; H10W 72/5525; H10W 74/111; H10W 90/756

(57) ABSTRACT

Power semiconductor device packages and methods for manufacturing the same are provided. In one example, a power semiconductor device package may include a housing, a submount, and a semiconductor die on the submount. The power semiconductor device package may further include a bond structure. In one example, the bond structure may be at least partially exposed through a side of the housing and may be configured to provide a heat dissipation path through the side of the housing. In one example, the bond structure may be planarized relative to a side of the housing such that at least a portion of the bond structure is co-planar with the side of the housing.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a power semiconductor device package. The power semiconductor device package includes a housing, a submount, a semiconductor die on the submount, and a malleable bond structure at least partially exposed through a side of the housing. The malleable bond structure is configured to provide a heat dissipation path through the side of the housing.

Another example aspect of the present disclosure is directed to a power semiconductor device package. The power semiconductor device package includes a housing, a submount, a semiconductor die on the submount, and a malleable bond structure coupled to the semiconductor die. At least a portion of the malleable bond structure is co-planar with a major side of the housing.

Another example aspect of the present disclosure is directed to a method. The method includes providing a semiconductor die on a submount. The method further includes providing a bond structure on the semiconductor die. The method further includes providing an encapsulating material around the semiconductor die, the submount, and the bond structure to form a housing. The method further includes planarizing the bond structure relative to a major side of the housing to form a power semiconductor device package.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a top schematic view of an example power semiconductor device package;

FIG. 2 depicts a side schematic view of an example power semiconductor device package;

FIG. 3 depicts a top plan view of an example power semiconductor device package;

FIG. 4 depicts a bottom plan view of an example power semiconductor device package;

FIG. 5 depicts a top schematic view of an example power semiconductor device package according to example embodiments of the present disclosure;

FIG. 6 depicts a side schematic view of an example power semiconductor device package according to example embodiments of the present disclosure;

FIG. 7 depicts a top plan view of an example power semiconductor device package according to example embodiments of the present disclosure;

FIG. 8 depicts a bottom plan view of an example power semiconductor device package according to example embodiments of the present disclosure;

FIGS. 9A-9D depict cross-sectional views of example bond structures according to example embodiments of the present disclosure;

FIG. 10 depicts an overview of an example method according to example embodiments of the present disclosure;

FIG. 11 depicts a top schematic view of an example power semiconductor device package according to example embodiments of the present disclosure;

FIG. 12 depicts a top plan view of an example power semiconductor device package according to example embodiments of the present disclosure;

FIG. 13 depicts a top plan view of an example power semiconductor device package according to example embodiments of the present disclosure;

FIG. 14 depicts a top schematic view of an example power semiconductor device package according to example embodiments of the present disclosure;

FIG. 15 depicts a top plan view of an example power semiconductor device package according to example embodiments of the present disclosure;

FIG. 16 depicts a top schematic view of an example power semiconductor device package according to example embodiments of the present disclosure;

FIG. 17 depicts a top plan view of an example power semiconductor device package according to example embodiments of the present disclosure; and

FIG. 18 depicts a flowchart diagram of an example method according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die. In some examples, such semiconductor die include one or more semiconductor devices, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Example aspects of the present disclosure are directed to power semiconductor device packages for use in semiconductor applications and other electronic applications. It should be understood that the terms “semiconductor device package,” “semiconductor package,” “power semiconductor device package,” and/or “power semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a MOSFET, such as a silicon carbide-based MOSFET. In such examples, the MOSFET(s) may be located between a first (e.g., source) lead and a second (e.g., drain) lead of a power semiconductor device package to form, for instance, a vertical structure power semiconductor device. Additionally and/or alternatively, in some examples, the one or more semiconductor die may include a Schottky diode, such as a silicon carbide-based Schottky diode. In such examples, the Schottky diode(s) may be located between a first (e.g., cathode) lead and a second (e.g., anode) lead of a power semiconductor device package to form, for instance, a vertical structure power semiconductor device. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices for purposes of illustration and discussion. Those having ordinary skill in the art, using the disclosures provided herein, will understand that the power semiconductor package of the present disclosure may include other power semiconductor devices without deviating from the scope of the present disclosure, such as diodes (e.g., Schottky diodes, PiN diodes, etc.), insulated gate bipolar transistors, HEMTs, or other devices. Furthermore, it should be understood that aspects of the present disclosure are discussed with reference to vertical structure power semiconductor devices for purposes of illustration and discussion. Those having ordinary skill in the art, using the disclosures provided herein, will understand that power semiconductor device packages of the present disclosure may include other forms of power semiconductor devices without deviating from the scope of the present disclosure, such as, by way of non-limiting example, horizontal structure power semiconductor devices and/or the like.

In some power semiconductor device packages, the one or more semiconductor die may be attached to a submount, such as a lead frame and/or a power substrate (e.g., direct bonded copper (DBC) substrate, active metal brazed (AMB) substrate, etc.), by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the power semiconductor device package may use wire bond(s) (e.g., aluminum (Al) wire bond(s), copper (Cu) wire bond(s), copper-clad aluminum (CCA) wire bond(s), aluminum-clad copper (ACC) wire bond(s), etc.) for interconnection between portions of the one or more semiconductor die (e.g., a gate contact) and the package (e.g., lead frame). Additionally and/or alternatively, in some examples, the power semiconductor device package may use ribbon bond(s) (e.g., aluminum (Al) ribbon bond(s), copper (Cu) ribbon bond(s), copper-clad aluminum (CCA) ribbon bond(s), aluminum-clad copper (ACC) ribbon bond(s), etc.) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The power semiconductor device package may further include a housing in which the one or more semiconductor die may be arranged. More particularly, in some examples, the housing may be and/or may include an encapsulating material (e.g., epoxy mold compound (EMC)) formed around at least a portion of the submount and the one or more semiconductor die. Hence, in some examples, the power semiconductor device package may be a discrete power semiconductor device package. The power semiconductor device package may also include one or more electrical leads extending from the housing. In some examples, the power semiconductor device package may include a plurality of electrical leads, each of which extending from a same side of the housing relative to one another. In other examples, the power semiconductor device package may include a plurality of electrical leads, at least one of which extending from a different side of the housing relative to the other electrical leads. It should be understood that, as used herein, a “plurality of electrical leads” includes at least two, or more, electrical leads extending from the housing.

The power semiconductor device package may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Packaging technology for semiconductor devices plays an important role in defining the performance of the semiconductor devices. For example, the packaging of a power semiconductor device package may limit the ability of the one or more semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

Some power semiconductor device packages are packaged such that a metallization structure, such as a backside metallization structure that is coupled to a drain of the semiconductor die, is at least partially exposed through a side of the housing in order to provide a heat dissipation path for the semiconductor die through the side of the housing. However, in such examples, relying on the heat dissipation path provided by the exposed backside metallization structure may not be sufficient to address the performance-related effects associated with inadequate heat dissipation (e.g., discussed above).

Other power semiconductor device packages include metal clip(s) (instead of wire bond(s)) to couple the semiconductor die to the electrical leads. In such power semiconductor device packages, the metal clip(s) are at least partially exposed through a side of the housing in order to provide a heat dissipation path for the semiconductor die through the side of the housing. However, like the power semiconductor device packages that rely solely on an exposed backside metallization structure, relying on the heat dissipation path provided by the exposed metal clip(s) may not be sufficient to address the performance-related effects associated with inadequate heat dissipation (e.g., discussed above). Moreover, introducing metal clip(s) to the power semiconductor device package may introduce additional manufacturing-related issues, such as packaging issues, due primarily to the rigidity associated with metal clip(s).

Accordingly, to reduce the adverse performance-related effects associated with inadequate heat dissipation and to increase one or more operating characteristics of the power semiconductor device package (e.g., operating voltage, rated current, switching, etc.), example aspects of the present disclosure are directed to power semiconductor device packages having a housing, a submount, a semiconductor die on the submount, and a plurality of electrical leads extending from the housing. Furthermore, the power semiconductor device packages of the present disclosure may further include a malleable bond structure that is at least partially exposed through a side of the housing (e.g., major side of the housing). In this way, a malleable bond structure of the present disclosure may be configured to provide a heat dissipation path through the side of the housing (e.g., major side of the housing).

As described herein, a “malleable” bond structure refers to a bond structure that is capable of being planarized (e.g., flattened) during fabrication of the corresponding power semiconductor device package. That is, a shape of an example “malleable” bond structure may be modified (e.g., planarized relative to a major side of the housing) based on an applied compressive force that induces a plastic deformation of the “malleable” bond structure. However, as discussed in greater detail below, an example “malleable” bond structure may be configured such that it does not break, crack, and/or the like in response to the compressive force applied by the mold structure. In some examples, a “malleable” bond structure of the present disclosure may be planarized by a mold structure (e.g., mold chase) during fabrication of the power semiconductor device package. However, those having ordinary skill in the art, using the disclosures provided herein, will understand that example bond structures of the present disclosure may be planarized using any suitable method, process, structure, etc. without deviating from the scope of the present disclosure.

More particularly, a power semiconductor device package of the present disclosure may include a housing that, in some examples, includes an encapsulating material (e.g., epoxy mold compound (EMC)). For instance, the housing may include one or more “major” sides and one or more “minor” sides. As used herein, a “major side(s)” and/or a “major surface(s)” refers to a primary (e.g., most significant) surface(s) of the housing, such as the principal face(s) of the housing, the side(s) having the largest surface area, and/or the like. Conversely, a “minor side(s)” and/or a “minor surface(s)” refers to a secondary (e.g., less prominent) surface(s) of the housing relative to the “major side(s),” such as the side surface(s) of the housing, the side(s) having a smaller surface area relative to the principal faces, and/or the like. It should be understood that, when describing the housing, the terms “surface” and “side” may be used interchangeably.

More particularly, the housing may include a first major side (e.g., front/top side) and a second major side (e.g., back/bottom/rear side, etc.) that is generally opposite the first major side. The first major side and the second major side may be generally parallel relative to one another. The housing may further include one or more minor sides extending between the first major side and the second major side. For instance, in some examples, the housing may include a first minor side (e.g., bottom-side surface) and a second minor side (e.g., top-side surface) that is generally opposite the first minor side. The first minor side and the second minor side may be generally perpendicular to the first major side and the second major side. The first minor side and the second minor side may be generally parallel relative to one another. The housing may further include a third minor side (e.g., right-side surface) and a fourth minor side (e.g., left-side surface) opposite the third minor side. The third minor side and the fourth minor side may be generally perpendicular to the first major side and the second major side; likewise, the third minor side and the fourth minor side may be perpendicular to the first minor side and the second minor side. The third minor side and the fourth minor side may be generally parallel relative to one another.

The power semiconductor device package of the present disclosure may further include one or more semiconductor die at least partially within the housing. More particularly, the power semiconductor device package may include at least one semiconductor die arranged within the housing. In some examples, the semiconductor die may include a wide bandgap semiconductor material, such as silicon carbide (SiC), a Group-III nitride (e.g., gallium nitride (GaN)), and/or the like. As described in greater detail below, each semiconductor die may include one or more semiconductor devices. For instance, in some examples, the semiconductor die may include a metal-oxide-semiconductor field-effect transistor (MOSFET) (e.g., a silicon carbide-based MOSFET), a Schottky diode (e.g., a Group-III nitride-based Schottky diode), a high electron mobility transistor (HEMT) device (e.g., a Group-III nitride-based HEMT device), and/or the like.

The semiconductor die may be arranged (e.g., provided) on a mounting substrate, such as a submount. For instance, in some examples, the semiconductor die may be arranged on a lead frame. In some examples, at least a portion of the lead frame may be at least partially exposed through a side of the housing (e.g., major side of the housing) to provide a heat dissipation path (e.g., cooling path) for the semiconductor die arranged within the housing. Additionally and/or alternatively, in some examples, the semiconductor die may be arranged on a power substrate, such as a direct bonded copper (DBC) substrate, an active metal brazed (AMB) substrate, and/or the like. As discussed in greater detail below, the power substrate may include a plurality of metal layers and an insulating layer between the metal layers. In some examples, at least a portion of the power substrate may be at least partially exposed through a side of the housing (e.g., major side of the housing) to provide a heat dissipation path (e.g., cooling path) for the semiconductor die arranged within the housing. Additionally and/or alternatively, in some examples, the semiconductor die may be arranged on a lead frame, and the lead frame may be arranged on a power substrate. In some examples, at least a portion of the power substrate, on which the lead frame is arranged, may be at least partially exposed through a side of the housing (e.g., major side of the housing) to provide a heat dissipation path (e.g., cooling path) for the semiconductor die arranged within the housing.

The power semiconductor device package of the present disclosure may include a plurality of electrical leads extending from the housing. In some examples, each of the plurality of electrical leads may extend from a same side of the housing relative to one another. In other examples, at least one electrical lead of the plurality of electrical leads may extend from a different side of the housing relative to at least one other electrical lead. Those having ordinary skill in the art, using the disclosures provided herein, will understand that power semiconductor device packages of the present disclosure may include any suitable electrical lead without deviating from the scope of the present disclosure, such as extended lead(s), surface mount type (SMT) connection structure(s), Gull-wing pin(s), and/or the like.

In some examples, the power semiconductor device package of the present disclosure may also include a thermal pad. The thermal pad may be arranged on and/or at least partially exposed through a side of the housing. In this way, the thermal pad may provide for cooling of the power semiconductor device package through one of the major sides of the housing (e.g., top-side cooling, bottom-side cooling, dual-side cooling, etc.). The thermal pad may be electrically isolated from the plurality of electrical leads. In some examples, the thermal pad may be electrically isolated from the one or more semiconductor die arranged within the housing. In some examples, the thermal pad may be coupled to a drain contact of the semiconductor die. In some examples, the thermal pad may allow for the attachment of a heat sink (e.g., with an electrical isolator) to enhance thermal performance.

As noted above, example power semiconductor device packages of the present disclosure further include a “malleable” bond structure (hereinafter, “bond structure”). In some examples, the bond structure may be ultrasonically bonded to the semiconductor die. As used herein, the term “bonding” or “bonding process” refers to causing a transition of a material from a first form to a second form. A “bonding process” may or may not require attaching a component to the material.

The bond structure may include copper (Cu), aluminum (Al), copper-clad aluminum (CCA), aluminum-clad copper (ACC), and/or the like. In some examples, the bond structure may have a rectangular cross-section. For instance, in some examples, the bond structure may include one or more wire bond(s), such as a plurality of adjacent wire bonds. In other examples, the bond structure may include a circular cross-section. For instance, in some examples, the bond structure may include one or more ribbon bonds. In some examples, the bond structure may be coupled to at least one metallization structure (e.g., metal contact(s)) of the semiconductor die. In some examples, the bond structure may be coupled to a non-metal region of the semiconductor die.

As will be discussed in greater detail below, at least a portion of the bond structure may be at least partially exposed through a side of the housing, such as a major side of the housing. In this way, the bond structure may be configured to provide an additional heat dissipation path through the side of the housing. More particularly, in some examples, an exposed portion of the bond structure may be co-planar with the major side (e.g., top side) of the housing. That is, a shape of the bond structure may be modified (e.g., planarized) during fabrication of the power semiconductor device package. For instance, during the fabrication process, a compressive force may be applied to the bond structure that induces a plastic deformation of the bond structure, thereby planarizing the bond structure relative to the major side (e.g., top side) of the housing. As one non-limiting example, at least a portion of the bond structure may be planarized by a mold structure (e.g., mold chase) during fabrication of the power semiconductor device package. However, those having ordinary skill in the art, using the disclosures provided herein, will understand that the bond structures of the present disclosure may be modified (e.g., planarized) using any suitable method, process, structure, etc. without deviating from the scope of the present disclosure.

In some examples, the power semiconductor device package may undergo a removal process, such as a deflashing process and/or the like, to expose the co-planar portion of the bond structure. More particularly, in some examples, a portion of the housing (e.g., encapsulating material) may at least partially cover the planarized portion of the bond structure following encapsulation. The excess material that remains on the planarized portion of the bond structure may be removed using any suitable removal process and/or deflashing process, such as, by way of non-limiting example, mechanical deflashing/removal (e.g., cutting, grinding, blasting, brushing, trimming, etc.), thermal deflashing/removal (e.g., burning, etc.), chemical deflashing/removal (e.g., dissolving), laser deflashing/removal, and/or the like. As such, the planarized portion of the bond structure may be exposed through a side of the housing and, as such, may be configured to provide a heat dissipation path through the side of the housing.

As used herein, the terms “deflash,” “deflashing,” “deflashing process,” “remove,” “removal,” “removal processes,” and/or the like refers to a post-mold process whereby excess material (e.g., material remaining following encapsulation) is removed from one or more surfaces of a power semiconductor device package. Those having ordinary skill in the art, using the disclosures provided herein, will understand that any suitable deflashing process and/or other removal process may be used without deviating from the scope of the present disclosure.

In some examples, an example power semiconductor device package of the present disclosure may include more than one bond structure at least partially exposed through the major side (e.g., top side) of the housing. For instance, in some examples, the power semiconductor device package may include a first bond structure and a second bond structure that is spaced apart from the first bond structure. In such examples, the first bond structure may be configured to provide a first heat dissipation path through the major side (e.g., top side) of the housing, and the second bond structure may be configured to provide a second heat dissipation path through a side of the housing that is different from the first heat dissipation path. In some examples, the first heat dissipation path and the second heat dissipation path may be through the same major side of the housing. In other examples, the second heat dissipation path may be through an opposing major side of the housing relative to the first heat dissipation path.

Aspects of the present disclosure provide a number of technical effects and benefits. For instance, example aspects of the present disclosure provide a power semiconductor device package that includes at least one bond structure at least partially exposed through a side (e.g., top side) of the housing. In this way, the bond structure(s) may provide efficient thermal dissipation (e.g., heat dissipation) for a semiconductor die through the side of the housing. By increasing and/or enhancing the thermal efficiency, example aspects of the present disclosure provide increased current and voltage capabilities for semiconductor packages, such as discrete power semiconductor device packages, thereby providing for increased reliability and longevity of high-voltage semiconductor devices. Moreover, the bond structure may be ultrasonically bonded to the semiconductor die, thereby allowing the bond structure and/or metallization structures of the semiconductor die (e.g., contacts) to include non-solderable materials. Additionally, the bond structure may require less energy and/or lower temperatures to complete a bonding process which, in turn, may reduce damage to sensitive components of the power semiconductor device package during manufacturing. The reduced energy required for bonding may likewise reduce the overall energy required to manufacture the example power semiconductor device packages described herein, thereby reducing the overall manufacturing costs. Even further, by providing a malleable bond structure, the bond structure(s) described herein may be modified (e.g., planarized) during the manufacturing process which, in turn, reduces the cost and complexity of the manufacturing process. For instance, the malleable nature of the bond structures described herein also allows the example bond structures to be molded, planarized, etc. without the need for special use-specific equipment. Hence, example aspects of the present disclosure are widely applicable to many different power semiconductor device packages, semiconductor die, and/or the like.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

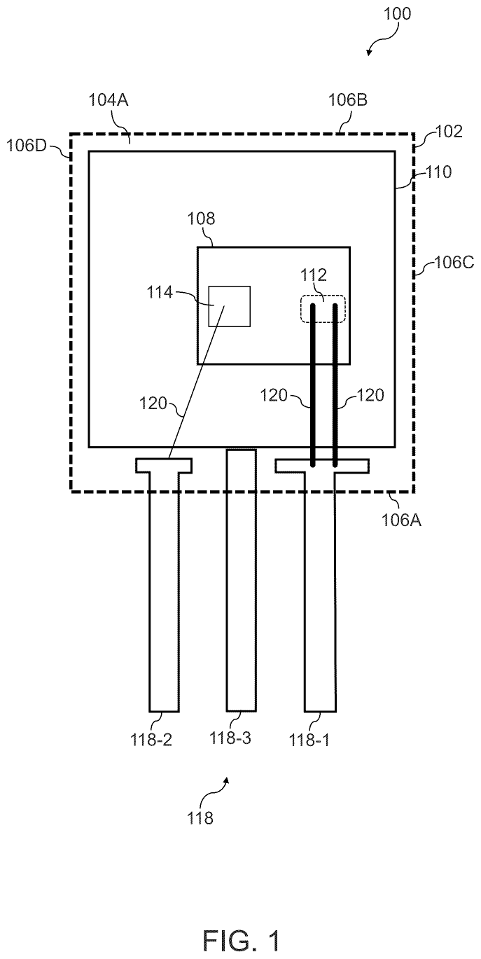

FIGS. 1-4 depict an example power semiconductor device package 100. Although the power semiconductor device package 100 is depicted and described herein as a discrete power semiconductor device package, those having ordinary skill in the art, using the disclosures provided herein, will understand that the example aspects described below may also be appliable to other power semiconductor device packages, such as power modules, integrated power systems, and/or the like, without deviating from the scope of the present disclosure.

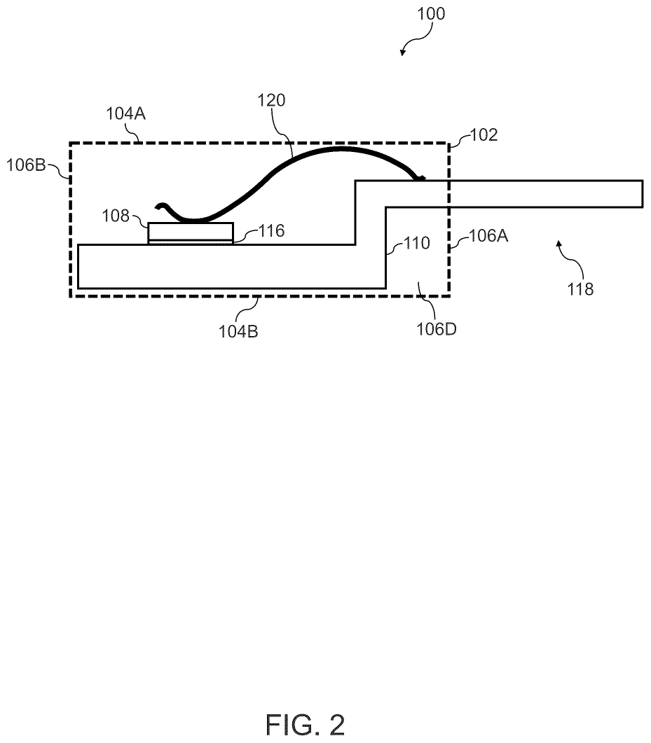

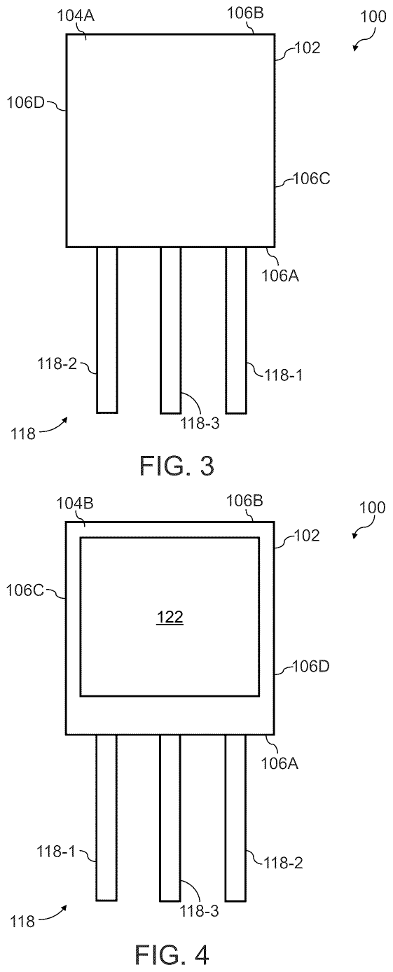

Referring now to FIGS. 1-4, FIG. 1 depicts a top schematic view of the power semiconductor device package 100, FIG. 2 depicts a side schematic view of the power semiconductor device package 100, FIG. 3 depicts a top plan view of the power semiconductor device package 100, and FIG. 4 depicts a bottom plan view of the power semiconductor device package 100. It should be understood that FIGS. 1-4 are intended to represent structures for purposes of identification and description and are not intended to represent the structures to physical scale.

As shown, the power semiconductor device package 100 includes a housing 102. The housing 102 may include a material capable of high temperature operation, such as a temperature of about 200° C. In some examples, the housing 102 may be and/or may include an encapsulating material. By way of non-limiting example, the housing 102 may be and/or may include an epoxy material, an epoxy mold compound (EMC), and/or the like. It should be understood that the housing 102 is depicted as transparent in FIGS. 1-2.

The housing 102 may include one or more surfaces and/or one or more sides. For instance, the housing may include one or more “major” sides 104 and one or more “minor” sides 106. As noted above, a “major side(s)” and/or a “major surface(s)” refers to a primary (e.g., most significant) surface(s) of the housing 102, such as the principal face(s) of the housing 102, the side(s) having the largest surface area, and/or the like. Conversely, a “minor side(s)” and/or a “minor surface(s)” refers to a secondary (e.g., less prominent) surface(s) of the housing 102 relative to the “major side(s),” such as the side surface(s) of the housing 102, the side(s) having a smaller surface area relative to the principal faces, and/or the like. It should be understood that, when describing the housing 102, the terms “surface” and “side” may be used interchangeably.

For instance, as shown, the housing 102 may include a first major side 104A (e.g., front/top side) (FIG. 3) and a second major side 104B (e.g., back/bottom/rear side) (FIG. 4) (collectively, “sides 104”). The second major side 104B may be generally opposite the first major side 104A. The first major side 104A and the second major side 104B are hereinafter referred to as side 104A and side 104B, respectively. As shown in FIGS. 3-4, the sides 104 may generally parallel relative to one another and may be the principal faces of the housing 102. The housing 102 may further include one or more minor sides 106 adjacent to and extending between the sides 104.

The housing 102 may further include a first minor side 106A (e.g., bottom-side surface), a second minor side 106B (e.g., top-side surface), a third minor side 106C (e.g., right-side surface), and a fourth minor side 106D (e.g., left-side surface) (collectively, “sides 106”). The first minor side 106A, the second minor side 106B, the third minor side 106C, and the fourth minor side 106D are hereinafter referred to as side 106A, side 106B, side 106C, and side 106D, respectively. The side 106B may be generally opposite the side 106A; the side 106D may be generally opposite the side 106C. The sides 106 may be generally perpendicular to the sides 104; the sides 106A, 106B may be generally perpendicular to the sides 106C, 106D. The sides 106A, 106B may be generally parallel relative to one another; the sides 106C, 106D may be generally parallel relative to one another.

It should be understood that the housing 102 may include different arrangements of surfaces without deviating from the scope of the present disclosure. For instance, one or more notches and/or one or more recesses may be formed on any of the sides and/or surfaces of the housing 102 without deviating from the scope of the present disclosure.

The power semiconductor device package 100 may be arranged to house and provide external connections to one or more semiconductor die, such as a semiconductor die 108. As shown, the semiconductor die 108 may be arranged within the housing 102. It should be understood that the power semiconductor device package 100 is depicted in FIGS. 1-4 as having one semiconductor die (e.g., semiconductor die 108) for purposes of illustration and discussion. Those having ordinary skill in the art, using the disclosures provided herein, will understand that example power semiconductor device packages of the present disclosure may include more than one semiconductor die without deviating from the scope of the present disclosure.

The semiconductor die 108 may be mounted on a mounting substrate, such as a submount 110. The semiconductor die 108 may be coupled to the submount 110 with, for instance, a die-attach material. In some examples, the semiconductor die 108 may be directly coupled to the submount 110. As will be discussed in greater detail below, in some examples, the submount 110 may be and/or may include a power substrate, such as a direct bonded copper (DBC) substrate, an active metal brazed (AMB) substrate, and/or the like. In some examples, the submount 110 may be and/or may include a lead frame, such as a conductive lead frame and/or the like. In some examples, the submount 110 may be and/or may include a lead frame, and the lead frame may be arranged on a power substrate.

In some examples, the semiconductor die 108 may include a wide bandgap semiconductor material, such as silicon carbide (SiC), a Group-III nitride (e.g., gallium nitride (GaN)), and/or the like. The semiconductor die 108 may include one or more semiconductor devices. For instance, in some examples (e.g., FIGS. 1-4), the semiconductor die 108 may include a metal-oxide-semiconductor field-effect transistor (MOSFET), such as a silicon carbide-based MOSFET. In other examples, the semiconductor die 108 may include a Schottky diode. It should be understood that the semiconductor die 108 is depicted in FIGS. 1-4 as including one or more MOSFETs for purposes of illustration and discussion. Those having ordinary skill in the art, using the disclosures provided herein, will understand that the semiconductor die 108 may include any suitable semiconductor device without deviating from the scope of the present disclosure.

As noted above, the semiconductor die 108 depicted in FIGS. 1-4 includes one or more MOSFETs. In such examples, the semiconductor die 108 may include one or more metallization structures, such as one or more contacts, on one or more sides of the semiconductor die 108. In particular, as shown in FIGS. 1-2, the semiconductor die 108 may include a source contact 112, a gate contact 114, and a drain contact 116. The source contact 112 and the gate contact 114 may, in some examples, be on a top side of the semiconductor die 108 (e.g., facing side 104A). The drain contact 116 may, in some examples, be on a back side of the semiconductor die 108 (e.g., facing side 104B). Although not depicted in FIGS. 1-2, in some examples, the semiconductor die 108 may further include one or more additional contacts on the top side of the semiconductor die 108, such as, by way of non-limiting example, a source-kelvin contact, a sensor contact, and/or the like.

Referring still to FIGS. 1-4, the power semiconductor device package 100 may include a plurality of electrical leads 118 extending from the housing 102. In some examples, the plurality of electrical leads 118 may extend from a minor side 106 of the housing, such as minor side 106A. More particularly, in some examples, the plurality of electrical leads 118 may extend from a perpendicular side of the housing 102 relative to the major sides 104. Each of the plurality of electrical leads 118 may be at least partially encapsulated by the housing 102 such that a portion of each of the plurality of electrical leads 118 is exposed through the side 106A. For instance, as shown, each of the plurality of electrical leads 118 may extend from a same side of the housing 102, such as, in the example of the power semiconductor device package 100 depicted in FIGS. 1-4, side 106A. The plurality of electrical leads 118 may have the form of electrical connection pins, such as extended leads. It should be understood that, although depicted herein as extended leads, the plurality of electrical leads 118 may have any suitable electrical connection pin and/or connection structure, such as surface mount type (SMT) connection structures, Gull-wing pins, and/or the like.

At least one electrical lead of the plurality of electrical leads 118 may be coupled to one or more contacts (e.g., source contact 112, gate contact 114, drain contact 116, additional contact (not shown), etc.) of the semiconductor die 108. For instance, in the example of the semiconductor die 108 including a MOSFET, the plurality of electrical leads 118 may include a first lead 118-1, a second lead 118-2, and a third lead 118-3. It should be understood that a power semiconductor device package of the present disclosure may include more than three electrical leads 118 without deviating from the scope of the present disclosure.

More particularly, the first lead 118-1 of the plurality of electrical leads 118 may be connected to the source contact 112 of the semiconductor die 108. In some examples, the first lead 118-1 may be connected to the source contact 112 using, for instance, one or more wire bonds 120. In this way, the first lead 118-1 may be used to connect the source of the semiconductor die 108 to one or more external connections.

The second lead 118-2 of the plurality of electrical leads 118 may be connected to the gate contact 114 of the semiconductor die 108. In some examples, the second lead 118-2 may be connected to the gate contact 114 using, for instance, one or more wire bonds 120. In this way, the second lead 118-2 may be used to connect the gate of the semiconductor die 108 to one or more external connections.

The third lead 118-3 of the plurality of electrical leads 118 may be connected to the drain contact 116 of the semiconductor die 108. In some examples, the third lead 118-3 may be connected to the drain contact 116 using, for instance, one or more wire bonds (not shown). In some examples (e.g., FIG. 2), the drain contact 116 of the semiconductor die 108 may be coupled to a lead frame (e.g., submount 110), and the third lead 118-3 of the plurality of electrical leads 118 may be coupled to the lead frame. In this way, the third lead 118-3 may be used to connect the drain of the semiconductor die 108 to one or more external connections.

It should be understood that the arrangement of the leads 118-1-118-3 of the plurality of electrical leads 118 is for purposes of illustration and discussion. Those having ordinary skill in the art, using the disclosures provided herein, will understand that the leads 118-1-118-3 may be rearranged, adjusted, etc. without deviating from the scope of the present disclosure.

Furthermore, as shown in FIG. 4, the power semiconductor device package 100 may, in some examples, further include a conductive structure, such as thermal pad 122 (e.g., drain pad), on a major side (e.g., side 104B) of the housing 102. In some examples, such as that depicted in FIG. 4, the thermal pad 122 may be at least partially exposed through the side 104B. Additionally and/or alternatively, in some examples, the thermal pad 122 may be electrically isolated from the plurality of electrical leads 118. In some examples, the thermal pad 122 may be coupled to the drain contact 116 of the semiconductor die 108. The thermal pad 122 may include a thermally conductive material, such as a metal, and may be coupled to an external heat sink (e.g., with an electrical isolator) to provide for cooling of the power semiconductor device package 100 through the major side (e.g., side 104B) of the housing 102. In this way, the thermal pad 122 may be operable to provide a heat dissipation path for the first semiconductor die 108 through the side 104B of the housing 102.

In some examples, the thermal pad 122 may also be electrically isolated from the semiconductor die 108 disposed within the housing 102. For instance, as described above, the semiconductor die 108, which is disposed within the housing 102, may be mounted on the submount 110 (e.g., mounting substrate) of the power semiconductor device package 100. The submount 110 may be coupled to, or integral with, the thermal pad 122. More particularly, although not depicted in FIGS. 1-4, the submount 110 may be and/or may form part of a power substrate (not shown), which includes a plurality of metal layers and an insulating layer between the metal layers. In such examples, the thermal pad 122 may be mounted on the insulating layer of the power substrate (not shown). In some examples (e.g., FIGS. 1-4), the thermal pad 122 may be and/or may form part of a lead frame (e.g., submount 110). In this manner, the thermal pad 122 may, in some examples, be electrically isolated from the semiconductor die 108.

Variations and modifications may be made to the example power semiconductor device package 100 described above to reduce the adverse performance-related effects (e.g., associated with inadequate heat dissipation) described herein and, thereby, increase one or more operating characteristics (e.g., operating voltage, rated current, switching, etc.). For instance, as described above, example power semiconductor device packages of the present disclosure may include a malleable bond structure that is configured to provide a heat dissipation path through the major side (e.g., top side) of the housing 102. As used herein, a “malleable” bond structure refers to a bond structure that is capable of being planarized (e.g., flattened) during the fabrication process. That is, example power semiconductor device packages of the present disclosure may include a bond structure that is configured to undergo a plastic deformation—without breaking, cracking, and/or the like—in response to a compressive force applied thereto during the fabrication process.

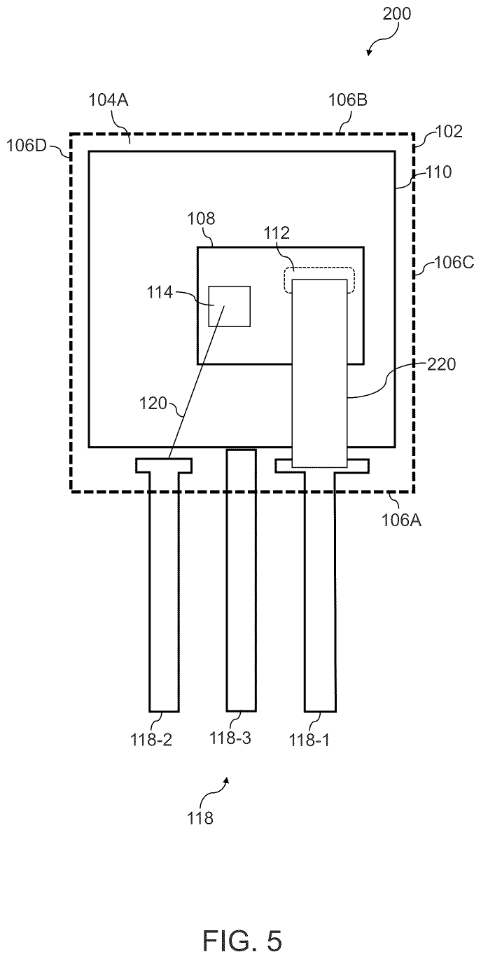

As one non-limiting illustrative example, FIGS. 5-8 depict an example power semiconductor device package 200 according to example embodiments of the present disclosure. Although the power semiconductor device package 200 is depicted and described herein as a discrete power semiconductor device package, those having ordinary skill in the art, using the disclosures provided herein, will understand that the example aspects described below may also be appliable to other power semiconductor device packages, such as power modules, integrated power systems, and/or the like, without deviating from the scope of the present disclosure.

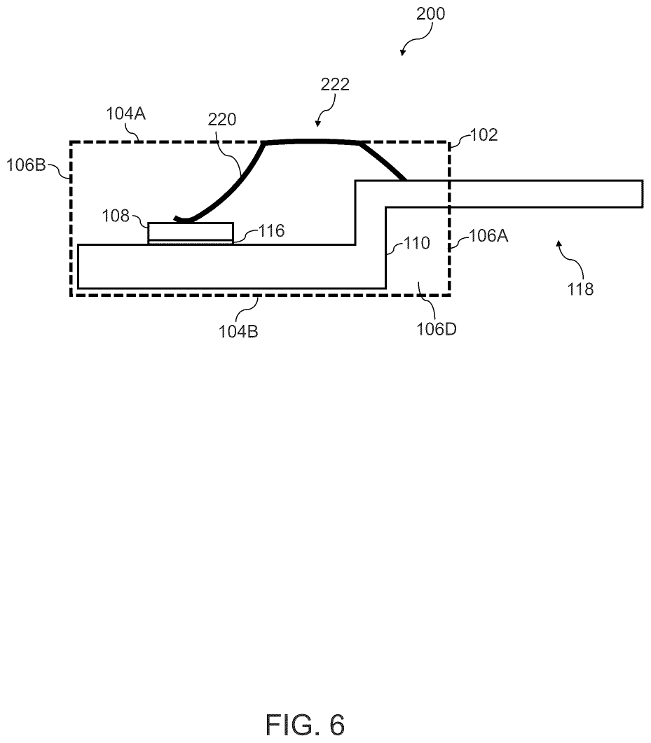

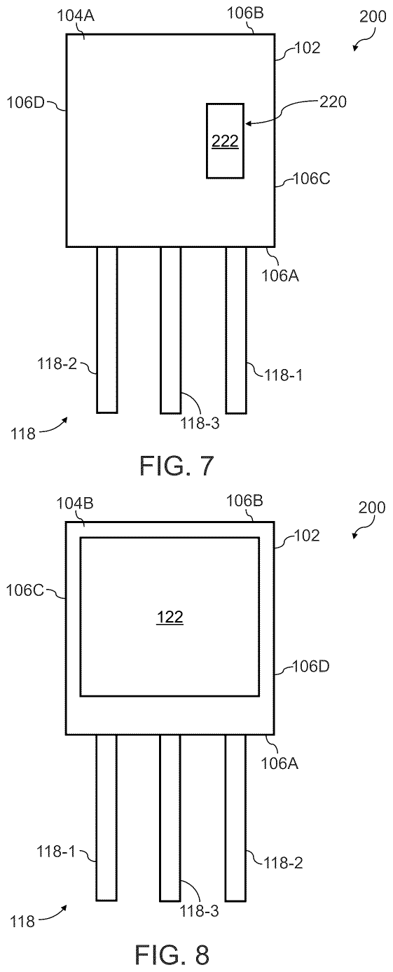

Referring now to FIGS. 5-8, FIG. 5 depicts a top schematic view of the power semiconductor device package 200, FIG. 6 depicts a side schematic view of the power semiconductor device package 200, FIG. 7 depicts a top plan view of the power semiconductor device package 200, and FIG. 8 depicts a bottom plan view of the power semiconductor device package 200. It should be understood that FIGS. 5-8 are intended to represent structures for purposes of identification and description and are not intended to represent the structures to physical scale.

The power semiconductor device package 200 depicted in FIGS. 5-8 may be similar to any of the example power semiconductor device packages described herein, such as the power semiconductor device package 100 (FIGS. 1-4) and/or the like. For instance, as shown, the power semiconductor device package 200 may include the housing 102. The power semiconductor device package 200 may further include the semiconductor die 108 on the submount 110. As shown, the semiconductor die 108 may include one or more semiconductor devices, such as one or more metal-oxide-semiconductor field-effect transistors (MOSFETs). However, those having ordinary skill in the art, using the disclosures provided herein, will understand that the semiconductor die 108 may include any suitable semiconductor device (e.g., Schottky diode, high electron mobility transistor (HEMT) device, etc.) without deviating from the scope of the present disclosure. The power semiconductor device package 200 may further include the plurality of electrical leads 118 extending from the housing 102.

In contrast to the power semiconductor device package 100 described above (e.g., FIGS. 1-4), the power semiconductor device package 200 may include a malleable bond structure, such as the bond structure 220. As will be discussed in greater detail below, a shape of the bond structure 220 may be planarized during fabrication of the power semiconductor device package 200. It should be understood that, although depicted in FIGS. 5-8 as including one or more ribbon bonds, the bond structure 220 may include any suitable conductive structure having malleable physical properties without deviating from the scope of the present disclosure.

As shown in FIGS. 5-8, the bond structure 220 may be at least partially exposed through a major side 104 of the housing 102, such as major side 104A (e.g., top side). That is, an exposed portion 222 of the bond structure 220 may be co-planar with the major side 104A of the housing 102. In this way, the bond structure 220 may be configured to provide a heat dissipation path (e.g., thermal dissipation path, cooling path, etc.) through the major side 104A of the housing 102. Those having ordinary skill in the art, using the disclosures provided herein, will understand that the bond structure 220 may be at least partially exposed through other sides of the housing (e.g., major sides 104, minor sides 106) without deviating from the scope of the present disclosure.

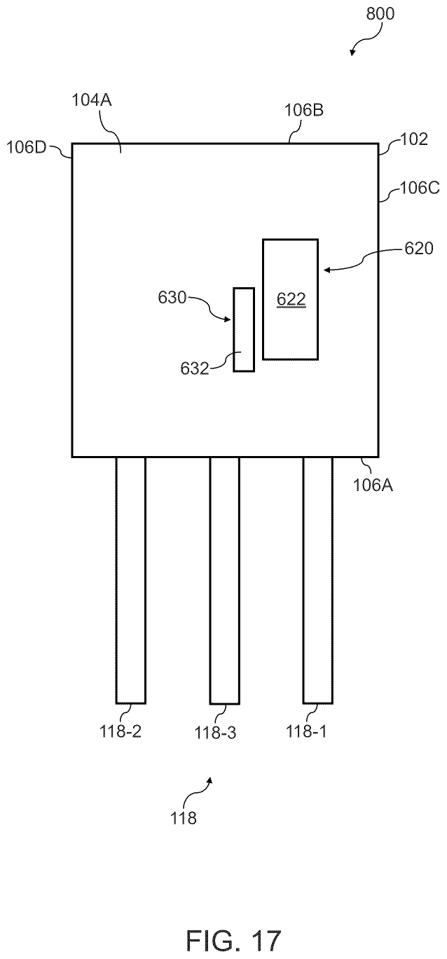

The bond structure 220 may be ultrasonically bonded to the semiconductor die 108. In some examples, the bond structure 220 may be coupled to at least one metallization structure (e.g., metal contact) of the semiconductor die 108. For instance, as shown in the example depicted in FIGS. 5-8, the bond structure 220 may be coupled to the source contact 112 of the semiconductor die 108. However, as will be discussed in greater detail below, the bond structure 220 may be coupled to any suitable metallization structure (e.g., gate contact 114, drain contact 116, additional contact (not shown), etc.) and/or any suitable non-meal region of the semiconductor die 108 without deviating from the scope of the present disclosure. Furthermore, in some examples, the bond structure 220 may be coupled to at least one of the plurality of electrical leads 118. For instance, as shown in the example depicted in FIGS. 5-8, the bond structure 220 may be coupled (e.g., electrically coupled) to the source lead 118-1 of the plurality of electrical leads 118. Additionally and/or alternatively, in other examples (e.g., FIGS. 16-17), the bond structure 220 may not be coupled (e.g., electrically coupled) to any of the plurality of electrical leads 118.

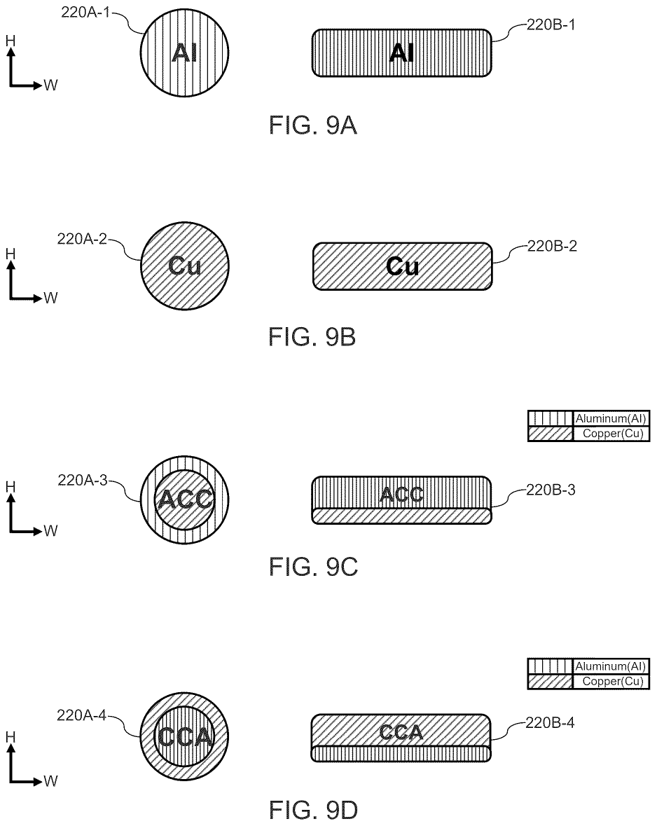

Referring briefly to FIGS. 9A-9D, cross-sectional views of example bond structures 220 are depicted according to example embodiments of the present disclosure. It should be understood that FIGS. 9A-9D are intended to represent structures for purposes of identification and description and are not intended to represent the structures to physical scale.

The bond structure 220 may include any suitable conductive material, such as, by way of non-limiting example, aluminum (Al), copper (Cu), and/or the like. For instance, in some examples (e.g., FIG. 9A), the bond structure 220 may include aluminum (Al). Additionally and/or alternatively, in some examples (e.g., FIG. 9B), the bond structure 220 may include copper (Cu). Additionally and/or alternatively, in some examples (e.g., FIGS. 9C-9D), the bond structure 220 may include more than one conductive material.

For instance, in some examples (e.g., FIG. 9C), the bond structure 220 may include aluminum-clad copper (ACC); in some examples (e.g., FIG. 9D), the bond structure 220 may include copper-clad aluminum (CCA). As used herein, an “aluminum-clad copper” bond structure 220 refers to a bond structure 220 that includes an inner aluminum core and an outer copper cladding. Likewise, as used herein, a “copper-clad aluminum” bond structure 220 refers to a bond structure 220 that includes an inner copper core and an outer aluminum cladding.

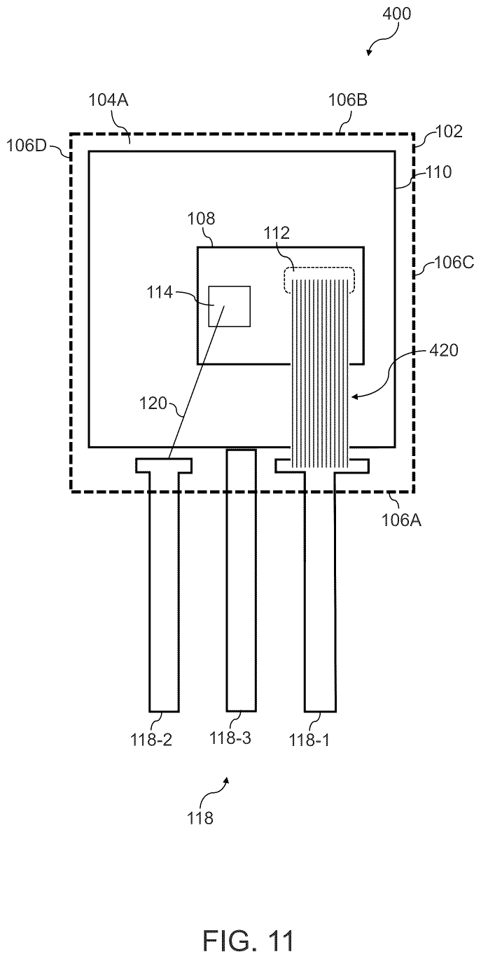

Referring still to FIGS. 9A-9D, as shown, the bond structure 220 may include a height H and a width W. In some examples, each bond structure 220 may have a thickness T in a range of about 50 microns to about 1000 microns, such as a thickness T in a range of about 100 microns to about 800 microns, such as a thickness T in a range of about 200 microns to about 600 microns, such as a thickness T of about 500 microns. For instance, as shown, the bond structure 220 may, in some examples, have a circular cross-section (e.g., bond structure 220A-1 (FIG. 9A), bond structure 220A-2 (FIG. 9B), bond structure 220A-3 (FIG. 9C), bond structure 220A-4 (FIG. 9D)) (collectively, “bond structure 220A” and/or “bond structures 220A”). In such examples, the bond structure 220A may have a height-to-width ratio (e.g., aspect ratio) of about 1:1. For instance, by way of non-limiting example, the bond structure 220A may include one or more wire bonds. As will be discussed in greater detail below (e.g., FIG. 11), in some examples, the bond structure 220A may include a plurality of adjacent wire bonds. Additionally and/or alternatively, the bond structure 220 may, in some examples, have a rectangular cross-section (e.g., bond structure 220B-1 (FIG. 9A), bond structure 220B-2 (FIG. 9B), bond structure 220B-3 (FIG. 9C), bond structure 220B-4 (FIG. 9D)) (collectively, “bond structure 220B” and/or “bond structures 220B”). In such examples, the bond structure 220B may have a height-to-width ratio (e.g., aspect ratio) of less than about 1:1. For instance, by way of non-limiting example, the bond structure 220B may include one or more ribbon bonds.

FIGS. 9A-9D depict example bond structures 220A-220B for purposes of illustration and discussion. Those having ordinary skill in the art, using the disclosures provided herein, will understand that different bond structures having different conductive materials, shapes, aspect ratios, configurations, etc. may be used without deviating from the scope of the present disclosure.

In some examples, to further increase the corresponding thermal efficiency, example power semiconductor device packages of the present disclosure may further include additional heat dissipation paths. For instance, referring again to FIGS. 5-8 as one illustrative example, the heat dissipation path provided by the bond structure 220 may be a first heat dissipation path (e.g., through major side 104A). In such examples, the power semiconductor device package 200 may further include a conductive structure, such as the thermal pad 122, on a second major side (e.g., major side 104B) of the housing 102. As shown, the thermal pad 122 (e.g., conductive structure) may be a thermally conductive structure configured to provide a second heat dissipation path that is different and/or separate from the first heat dissipation path (e.g., provided by the bond structure 220). Put differently, the power semiconductor device package 200 may include a first heat dissipation path through the first (e.g., top) major side 104A (e.g., provided by the bond structure 220) and a second heat dissipation path through the second (e.g., bottom) major side 104B (e.g., provided by the thermal pad 122). Hence, in some examples, the power semiconductor device package 200 may include at least two separate and distinct heat dissipation paths, thereby increasing its overall thermal efficiency.

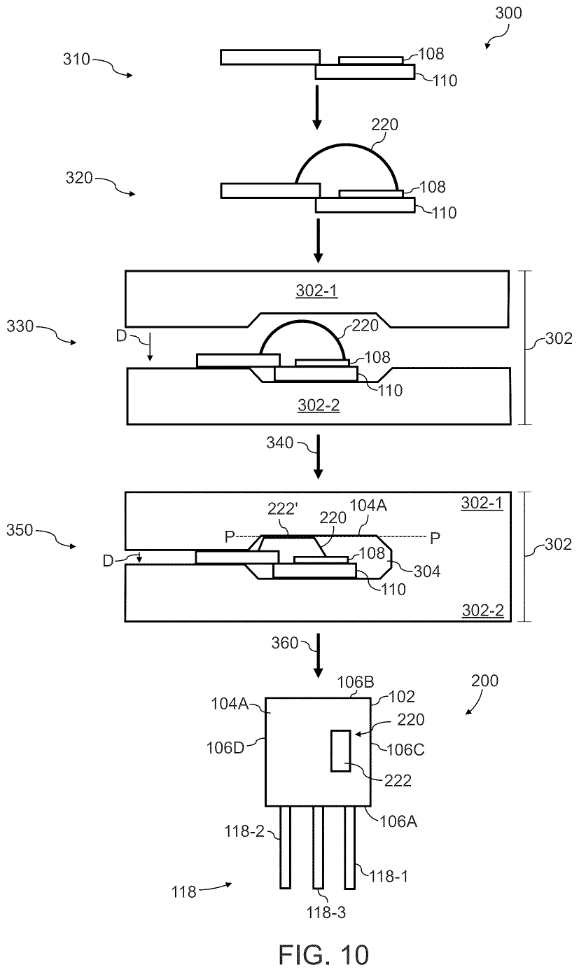

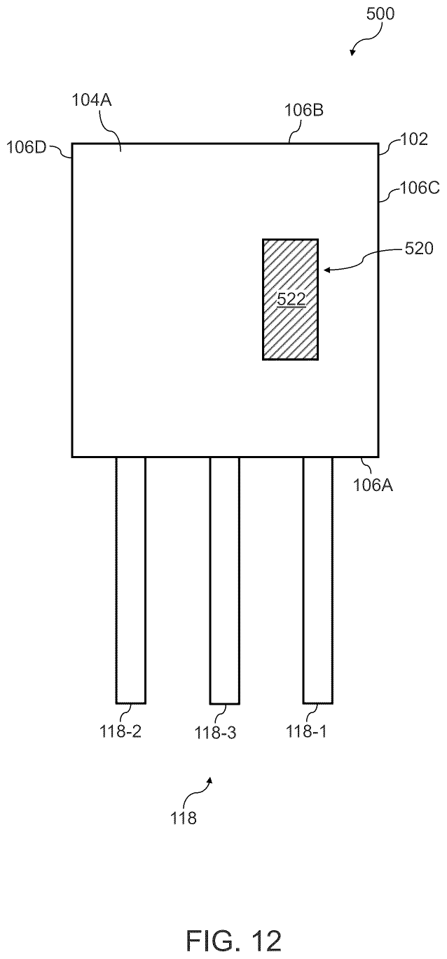

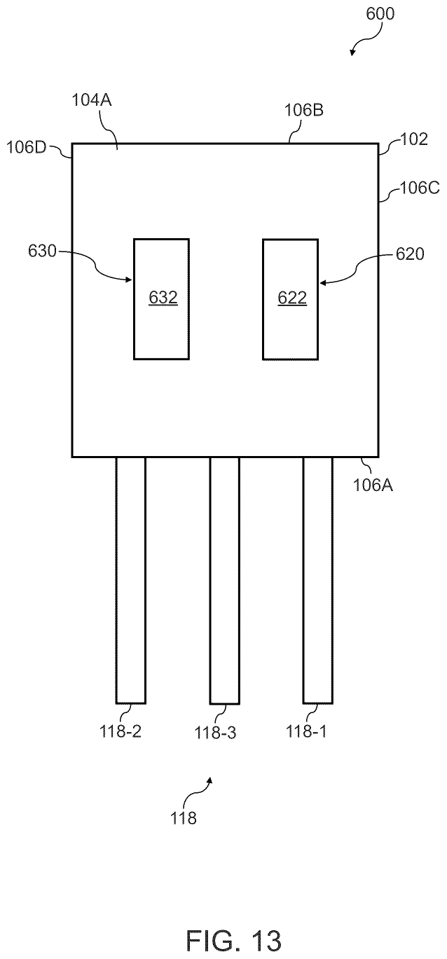

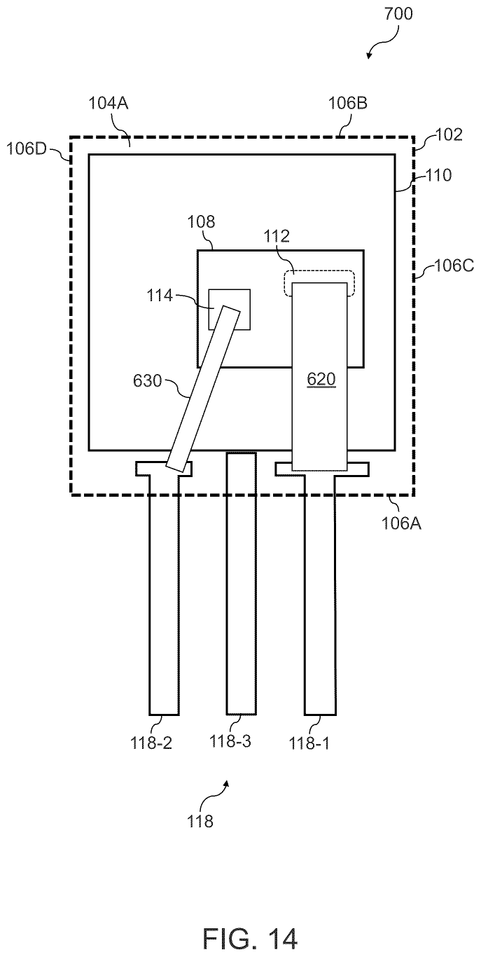

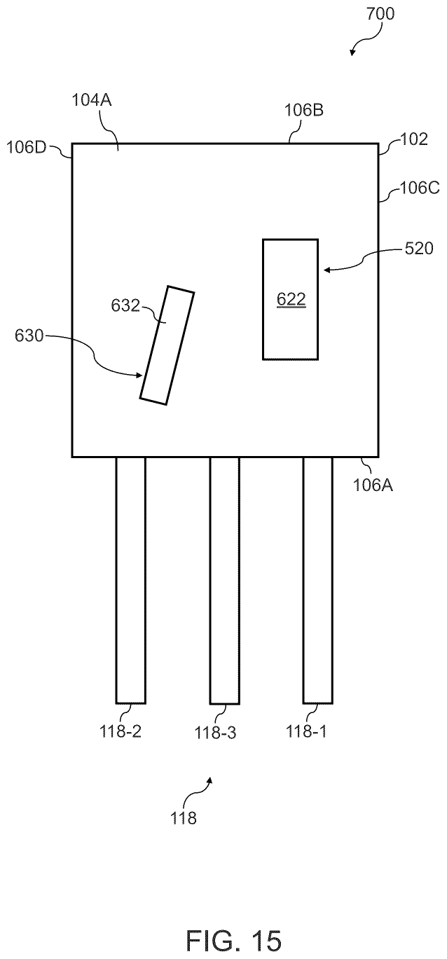

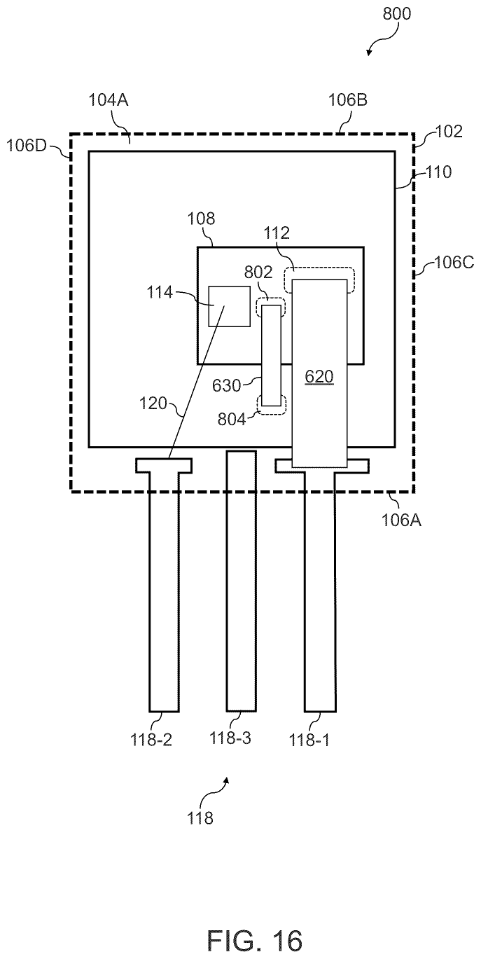

FIG. 10 depicts an illustrative overview of an example method 300 according to example embodiments of the present disclosure. As discussed in greater detail below, the method 300 depicted in FIG. 10 may be an illustrative overview of a process for fabricating the power semiconductor device package 200 described above with reference to FIGS. 5-8. However, those having ordinary skill in the art, using the disclosures provided herein, will understand that the example method 300 may serve to fabricate any of the example power semiconductor device packages described herein, such as the power semiconductor device package 100 (FIGS. 1-4), power semiconductor device package 400 (FIG. 11), power semiconductor device package 500 (FIG. 12), power semiconductor device package 600 (FIG. 13), power semiconductor device package 700 (FIGS. 14-15), power semiconductor device package 800 (FIGS. 16-17), and/or the like. FIG. 10 is intended to represent structures for identification and description and is not intended to represent the structures to physical scale. The method 300 includes operations illustrated in a particular order for purposes of illustration and discussion. Those having ordinary skill in the art, using the disclosures provided herein, will understand that the various steps or operations of any of the methods provided in this disclosure may be adapted, rearranged, omitted, include steps not illustrated, and/or modified in various ways without deviating from the scope of the present disclosure.

At 310, the semiconductor die 108 may be provided on the submount 110. For instance, in some examples, the semiconductor die 108 may be provided on the submount 110 using a die-attach material (not shown). As noted above, the semiconductor die 108 may include one or more semiconductor devices, such as a metal-oxide-semiconductor field-effect transistors (MOSFE), a Schottky diode, and/or the like.

At 320, the bond structure 220 may be provided on the semiconductor die 108. For instance, the bond structure 220 may be ultrasonically bonded to the semiconductor die 108. In some examples, the bond structure 220 may be coupled to at least one metallization structure of the semiconductor die 108, such as the source contact 112 (FIG. 5), the gate contact 114 (FIG. 5), and/or the like. Additionally and/or alternatively, in other examples, the bond structure 220 may be coupled to a non-metal region (not shown) of the semiconductor die 108. Furthermore, in some examples, a second bond structure (not shown) that is different from the bond structure 220 may also be provided on the semiconductor die 108. More particularly, as discussed in greater detail below, a second bond structure (not shown) may be provided on the semiconductor die 108 such that the second bond structure (not shown) is spaced apart from the bond structure 220. In such examples, the second bond structure (not shown) may provide a second heat dissipation path for the semiconductor die 108 that is different from the heat dissipation path provided by the bond structure 220. Those having ordinary skill in the art, using the disclosures provided herein, will understand that any number of bond structures 220 may be provided on the semiconductor die 108 without deviating from the scope of the present disclosure.

At 330, the semiconductor die 108, the submount 110, and the bond structure 220 may be provided to a mold structure 302 (e.g., mold chase). More particularly, as shown, the semiconductor die 108, the submount 110, and the bond structure 220 may be provided between an upper portion 302-1 of the mold structure 302 and a lower portion 302-2 of the mold structure 302. In the example depicted in FIG. 10, the mold structure 302 is in an open position at 330. However, as will be discussed in greater detail below, the mold structure 302 may be operable to move between the open position (e.g., at 330) and a closed position (e.g., at 350). That is, the upper portion 302-1 of the mold structure 302 may be operable to move in a direction D (e.g., towards the lower portion 302-2) in order to apply a compressive force to the components provided therein. It should be understood that the mold structure 302 may be any suitable mold structure without deviating from the scope of the present disclosure.

At 340, an encapsulating material 304 may be provided around the semiconductor die 108, the submount 110, and the bond structure 220. The encapsulating material 304 may be any suitable encapsulating material, such as, by way of non-limiting example, an epoxy material, an epoxy mold compound (EMC), and/or the like. The encapsulating material 304 may be molded directly onto and/or around the semiconductor die 108, the submount 110, and the bond structure 220, thereby forming the housing 102.

At 350, the mold structure 302 may move from the open position (e.g., at 330) to the closed position (e.g., at 350). That is, the upper portion 302-1 of the mold structure 302 may move towards the lower portion 302-2 of the mold structure 302 (e.g., in the direction D), which may result in a compressive force being applied to the bond structure 220. The compressive force applied by the mold structure 302 may induce a plastic deformation of the bond structure 220 that planarizes a shape of the bond structure 220. For instance, as shown, the compressive force applied by the bond structure 220 may deform the shape of the bond structure 220 such that at least a portion 222′ of the bond structure 220 becomes co-planar about a plane P defined by the major side 104A of the housing 102). It should be understood, however, that the planarization (e.g., modification) of the bond structure 220 depicted in FIG. 10 is for purposes of illustration and discussion. Those having ordinary skill in the art, using the disclosures provided herein, will understand that the bond structure 220 may be planarized using any suitable method, process, structure, etc. without deviating from the scope of the present disclosure.

At 360, at least a portion of the encapsulating material 304 (e.g., provided at 340) may be removed (e.g., deflashed, cut, trimmed, grinded, blasted, brushed, etc.) such that at least a portion of the bond structure 220 is exposed through the major side 104A of the housing 102. That is, subsequent to the planarization of the bond structure 220 (e.g., at 350), at least a portion of the encapsulating material 304 may, in some instances, be on the planarized portion 222′ of the bond structure 220. In such instances, the encapsulating material 304 that remains on the planarized portion 222′ of the bond structure 220 may be removed, trimmed, grinded, etc. (e.g., deflashed), thereby exposing the planarized portion 222′ of the bond structure 220 through the major side 104A of the housing 102. In this way, the power semiconductor device package 200 may be fabricated such that at least the exposed portion 222 of the bond structure 220 may provide a heat dissipation path through the major side 104A of the housing.

Those having ordinary skill in the art, using the disclosures provided herein, will understand that any suitable removal process may be used without deviating from the scope of the present disclosure.

Variations and modifications may be made to the example power semiconductor device package 200 described herein without deviating from the scope of the present disclosure. For instance, by way of non-limiting example, the bond structure 220 of the power semiconductor device package 200 may include one or more wire bonds (e.g., FIG. 11), the exposed portion 222 of the bond structure 220 may be anodized such that the bond structure 220 and the other internal components of the power semiconductor device package 200 may be electrically isolated (e.g., FIG. 12), the power semiconductor device package 200 may include more than one bond structure 220, and/or any combination thereof.

As one non-limiting illustrative example, FIG. 11 depicts a top schematic view of an example power semiconductor device package 400 according to example embodiments of the present disclosure. It should be understood that FIG. 11 is intended to represent structures for purposes of identification and description and is not intended to represent the structures to physical scale. Furthermore, although the power semiconductor device package 400 is depicted and described herein as a discrete power semiconductor device package, those having ordinary skill in the art, using the disclosures provided herein, will understand that the example aspects described below may also be appliable to other power semiconductor device packages, such as power modules, integrated power systems, and/or the like, without deviating from the scope of the present disclosure.

The power semiconductor device package 400 depicted in FIG. 11 may be similar to any of the example power semiconductor device packages described herein, such as the power semiconductor device package 100 (FIGS. 1-4), the power semiconductor device package 200 (FIGS. 5-8), and/or the like. In some examples, the power semiconductor device package 400 may be fabricated in a similar manner as set forth above with respect to the method 300 depicted in FIG. 10. For instance, as shown, the power semiconductor device package 400 may include the housing 102, the semiconductor die 108 on the submount 110, and the plurality of electrical leads 118 extending from the housing 102. It should be understood that the housing 102 is depicted as transparent in FIG. 11. Although not depicted in FIG. 11, the power semiconductor device package 400 may further include a conductive structure, such as the thermal pad 122 (FIG. 4), a drain pad, and/or the like.

The power semiconductor device package 400 may further include a bond structure 420. The bond structure 420 may be similar to any of the example bond structures described herein, such as the bond structure 220 (FIGS. 5-8) and/or the like. For instance, the bond structure 420 may be coupled to the semiconductor die 108, may be at least partially exposed through the major side 104A of the housing 102, and may be configured to provide a heat dissipation path through the major side 104A of the housing 102. However, in the example depicted in FIG. 11, the bond structure 420 may include a plurality of adjacent wire bonds. That is, the bond structure 420 may include a plurality of wire bonds that are laterally adjacent to one another. In such examples, the bond structure 420 may include any number of laterally-arranged wire bonds having any suitable shape, size, etc.

FIG. 11 depicts an example power semiconductor device package 400 having an example bond structure 420 for purposes of illustration and discussion. Those having ordinary skill in the art, using the disclosures provided herein, will understand that example power semiconductor device packages of the present disclosure may include different bond structures having different shapes, sizes, arrangements, configurations, etc. without deviating from the scope of the present disclosure.

As another non-limiting example, FIG. 12 depicts a top plan view of an example power semiconductor device package 500 according to example embodiments of the present disclosure. It should be understood that FIG. 12 is intended to represent structures for purposes of identification and description and is not intended to represent the structures to physical scale. Furthermore, although the power semiconductor device package 500 is depicted and described herein as a discrete power semiconductor device package, those having ordinary skill in the art, using the disclosures provided herein, will understand that the example aspects described below may also be appliable to other power semiconductor device packages, such as power modules, integrated power systems, and/or the like, without deviating from the scope of the present disclosure.

The power semiconductor device package 500 depicted in FIG. 12 may be similar to any of the example power semiconductor device packages described herein, such as the power semiconductor device package 100 (FIGS. 1-4), the power semiconductor device package 200 (FIGS. 5-8), the power semiconductor device package 400 (FIG. 11), and/or the like. In some examples, the power semiconductor device package 500 may be fabricated in a similar manner as set forth above with respect to the method 300 depicted in FIG. 10. For instance, the power semiconductor device package 500 may include the housing 102, the semiconductor die 108 (not shown) on the submount 110 (not shown), and the plurality of electrical leads 118 extending from the housing 102. Although not depicted in FIG. 12, the power semiconductor device package 500 may further include a conductive structure, such as the thermal pad 122 (FIG. 4), a drain pad, and/or the like.

The power semiconductor device package 500 may further include a bond structure 520. The bond structure 520 may be similar to any of the example bond structures described herein, such as the bond structure 220 (FIGS. 5-8), the bond structure 420 (FIG. 11), and/or the like. For instance, the bond structure 520 may be coupled to the semiconductor die 108 (not shown), may be at least partially exposed through the major side 104A of the housing 102, and may be configured to provide a heat dissipation path through the major side 104A of the housing 102. However, in the example depicted in FIG. 12, the bond structure 520 may include an anodized surface layer. That is, at least a portion of the bond structure 520—such as the portion that is exposed through the major side 104A of the housing 102 (e.g., exposed portion 522)—may be subjected to an anodization process that improves the insulating properties of the treated portion. In this way, at least the exposed portion 522 of the bond structure 520 may be electrically isolated from the semiconductor die 108 (not shown) and/or the other internal components of the power semiconductor device package 500.

It should be understood that anodizing the exposed portion 522 of the bond structure 520 is one illustrative and non-limiting way to electrically isolate the exposed portion 522 of the bond structure 520 from the semiconductor die 108 (not shown). Those having ordinary skill in the art, using the disclosures provided herein, will understand that the exposed portion 522 of the bond structure 520 may be electrically isolated from the semiconductor die 108 (not shown) in any suitable manner without deviating from the scope of the present disclosure.

It should be understood that, as used herein, an “anodization process” refers to any suitable process that forms a protective and/or functional oxide layer on a surface of a metal, such as the exposed portion 522 of the bonding structure 520. Furthermore, an “anodized” component refers to a component that has been subjected to an anodization process. Those having ordinary skill in the art, using the disclosures provided herein, will understand that any suitable anodization process may be used without deviating from the scope of the present disclosure.

FIG. 12 depicts an example power semiconductor device package 500 having an example bond structure 520 for purposes of illustration and discussion. Those having ordinary skill in the art, using the disclosures provided herein, will understand that example power semiconductor device packages of the present disclosure may include different bond structures having different shapes, sizes, arrangements, configurations, etc. without deviating from the scope of the present disclosure.

As noted above, in some examples, example power semiconductor device packages of the present disclosure may include more than one bond structure. As one non-limiting example, FIG. 13 depicts a top plan view of an example power semiconductor device package 600 according to example embodiments of the present disclosure. It should be understood that FIG. 13 is intended to represent structures for purposes of identification and description and is not intended to represent the structures to physical scale. Furthermore, although the power semiconductor device package 600 is depicted and described herein as a discrete power semiconductor device package, those having ordinary skill in the art, using the disclosures provided herein, will understand that the example aspects described below may also be appliable to other power semiconductor device packages, such as power modules, integrated power systems, and/or the like, without deviating from the scope of the present disclosure.

The power semiconductor device package 600 depicted in FIG. 13 may be similar to any of the example power semiconductor device packages described herein, such as the power semiconductor device package 100 (FIGS. 1-4), the power semiconductor device package 200 (FIGS. 5-8), the power semiconductor device package 400 (FIG. 11), the power semiconductor device package 500 (FIG. 12), and/or the like. In some examples, the power semiconductor device package 600 may be fabricated in a similar manner as set forth above with respect to the method 300 depicted in FIG. 10. For instance, the power semiconductor device package 600 may include the housing 102, the semiconductor die 108 (not shown) on the submount 110 (not shown), and the plurality of electrical leads 118 extending from the housing 102. Although not depicted in FIG. 13, the power semiconductor device package 600 may further include a conductive structure, such as the thermal pad 122 (FIG. 4), a drain pad, and/or the like.

However, in the example depicted in FIG. 13, the power semiconductor device package 600 includes a first malleable bond structure 620 (hereinafter, “bond structure 620”) and a second malleable bond structure 630 (hereinafter, “bond structure 630”). The bond structure 620 may be spaced apart from the bond structure 630.

The bond structure 620 and/or the bond structure 630 may be similar to any of the example bond structures described herein, such as the bond structure 220 (FIGS. 5-8), the bond structure 420 (FIG. 11), the bond structure 520 (FIG. 12), and/or the like. For instance, at least a portion of the bond structure 620 (e.g., exposed portion 622) may be co-planar with the major side 104A of the housing 102. Likewise, at least a portion of the bond structure 630 (e.g., exposed portion 632) may be co-planar with the major side 104A of the housing 102. In this way, the bond structure 620 may be configured to provide a first heat dissipation path through the major side 104A of the housing 102, and the bond structure 630 may be configured to provide a second heat dissipation path through the major side 104A of the housing 102. As shown, the first heat dissipation path (e.g., provided by bond structure 620) may be different from the second heat dissipation path (e.g., provided by bond structure 630).

FIG. 13 depicts an example power semiconductor device package 600 having example bond structures 620, 630 for purposes of illustration and discussion. Those having ordinary skill in the art, using the disclosures provided herein, will understand that example power semiconductor device packages of the present disclosure may include different bond structures having different shapes, sizes, arrangements, configurations, etc. without deviating from the scope of the present disclosure.

Variations and modifications may be made to the example power semiconductor device package 600 described herein without deviating from the scope of the present disclosure. As one non-limiting example, referring now to FIGS. 14-15, an example power semiconductor device package 700 having two bond structures (e.g., bond structure 620, bond structure 630) is depicted according to example embodiments of the present disclosure. More particularly, FIG. 14 depicts a top schematic view of the power semiconductor device package 700, and FIG. 15 depicts a top plan view of the power semiconductor device package 700. It should be understood that FIGS. 14-15 are intended to represent structures for purposes of identification and description and are not intended to represent the structures to physical scale. Furthermore, although the power semiconductor device package 700 is depicted and described herein as a discrete power semiconductor device package, those having ordinary skill in the art, using the disclosures provided herein, will understand that the example aspects described below may also be appliable to other power semiconductor device packages, such as power modules, integrated power systems, and/or the like, without deviating from the scope of the present disclosure.

The power semiconductor device package 700 depicted in FIGS. 14-15 may be similar to any of the example power semiconductor device packages described herein, such as the power semiconductor device package 100 (FIGS. 1-4), the power semiconductor device package 200 (FIGS. 5-8), the power semiconductor device package 400 (FIG. 11), the power semiconductor device package 500 (FIG. 12), the power semiconductor device package 600 (FIG. 13), and/or the like. In some examples, the power semiconductor device package 700 may be fabricated in a similar manner as set forth above with respect to the method 300 depicted in FIG. 10. For instance, as shown, the power semiconductor device package 700 may include the housing 102, the semiconductor die 108 on the submount 110, and the plurality of electrical leads 118 extending from the housing 102. It should be understood that the housing 102 is depicted as transparent in FIG. 14. Although not depicted in FIGS. 14-15, the power semiconductor device package 700 may further include a conductive structure, such as the thermal pad 122 (FIG. 4), a drain pad, and/or the like.

Like the power semiconductor device package 600 (FIG. 13), the power semiconductor device package 700 may include the bond structure 620 and the bond structure 630. As described above, the bond structure 620 may be configured to provide a first heat dissipation path through the major side 104A of the housing 102, and the bond structure 630 may be configured to provide a second heat dissipation path through the major side 104A of the housing 102 that is different from the first heat dissipation path (e.g., provided by the bond structure 620).

In some examples, each bond structure 620, 630 may be coupled to at least one metallization structure of the semiconductor die 108. For instance, as shown in FIG. 14, the bond structure 620 may be coupled to the source contact 112 of the semiconductor die 108. The bond structure 620 may also be coupled to the source lead 118-1 of the plurality of electrical leads 118. Likewise, the bond structure 630 may be coupled to the gate contact 114 of the semiconductor die 108. The bond structure 630 may also be coupled to the gate lead 118-2 of the plurality of electrical leads 118. Although not depicted in FIGS. 14-15, a conductive structure (e.g., thermal pad 122 (FIG. 4)) may be coupled to the drain contact 116 (not shown).

FIGS. 14-15 depict an example power semiconductor device package 700 having example bond structures 620, 630 for purposes of illustration and discussion. Those having ordinary skill in the art, using the disclosures provided herein, will understand that example power semiconductor device packages of the present disclosure may include different bond structures having different shapes, sizes, arrangements, configurations, etc. without deviating from the scope of the present disclosure.

As another non-limiting example, referring now to FIGS. 16-17, an example power semiconductor device package 800 having two bond structures (e.g., bond structure 620, bond structure 630) is depicted according to example embodiments of the present disclosure. More particularly, FIG. 16 depicts a top schematic view of the power semiconductor device package 800, and FIG. 17 depicts a top plan view of the power semiconductor device package 800. It should be understood that FIGS. 16-17 are intended to represent structures for purposes of identification and description and are not intended to represent the structures to physical scale. Furthermore, although the power semiconductor device package 800 is depicted and described herein as a discrete power semiconductor device package, those having ordinary skill in the art, using the disclosures provided herein, will understand that the example aspects described below may also be appliable to other power semiconductor device packages, such as power modules, integrated power systems, and/or the like, without deviating from the scope of the present disclosure.

The power semiconductor device package 800 depicted in FIGS. 16-17 may be similar to any of the example power semiconductor device packages described herein, such as the power semiconductor device package 100 (FIGS. 1-4), the power semiconductor device package 200 (FIGS. 5-8), the power semiconductor device package 400 (FIG. 11), the power semiconductor device package 500 (FIG. 12), the power semiconductor device package 600 (FIG. 13), the power semiconductor device package 700 (FIGS. 14-15), and/or the like. In some examples, the power semiconductor device package 800 may be fabricated in a similar manner as set forth above with respect to the method 300 depicted in FIG. 10. For instance, as shown, the power semiconductor device package 800 may include the housing 102, the semiconductor die 108 on the submount 110, and the plurality of electrical leads 118 extending from the housing 102. It should be understood that the housing 102 is depicted as transparent in FIG. 16. Although not depicted in FIGS. 16-17, the power semiconductor device package 800 may further include a conductive structure, such as the thermal pad 122 (FIG. 4), a drain pad, and/or the like.

Like the power semiconductor device package 600 (FIG. 13) and the power semiconductor device package 700 (FIGS. 14-15), the power semiconductor device package 800 may include the bond structure 620 and the bond structure 630. As described above, the bond structure 620 may be configured to provide a first heat dissipation path through the major side 104A of the housing 102, and the bond structure 630 may be configured to provide a second heat dissipation path through the major side 104A of the housing 102 that is different from the first heat dissipation path (e.g., provided by the bond structure 620).

In contrast to the power semiconductor device package 700 (FIGS. 14-15), at least one bond structure of the power semiconductor device package 800 may, in some examples, be coupled to a non-metal region of the semiconductor die 108. For instance, as shown in FIG. 16, the bond structure 620 may be coupled to a portion of the semiconductor die 108 that includes a metallization structure (e.g., source contact 112), and the bond structure 630 may be coupled to a portion of the semiconductor die 108 that includes no metallization structures (e.g., non-metal region 802). Additionally and/or alternatively, in other examples (not shown), each of the bond structures 620, 630 may be coupled to a non-metal region of the semiconductor die 108. It should be understood that, although depicted as being coupled to the non-metal region 802, the bond structure 630 may be coupled to any suitable non-metal region of the power semiconductor device package 800 without deviating from the scope of the present disclosure.

In further contrast to the power semiconductor device package 700 (FIGS. 14-15), at least one bond structure of the power semiconductor device package 800 may not, in some examples, be electrically coupled to any of the plurality of electrical leads 118. For instance, as shown in FIG. 16, while the bond structure 620 may be coupled to one of the plurality of electrical leads 118 (e.g., source lead 118-1), the bond structure 630 may not be electrically coupled to any of the plurality of electrical leads 118 and, instead, may be coupled to another non-metal region of the power semiconductor device package 800. Additionally and/or alternatively, in other examples (not shown), each of the bond structures 620, 630 may not be electrically coupled to any of the electrical leads 118 and, instead, may both be coupled to another non-metal region of the power semiconductor device package 800, such as, by way of non-limiting example, non-metal region 804. It should be understood that, although depicted as being coupled to the non-metal region 804, the bond structure 630 may be coupled to any suitable non-metal region of the power semiconductor device package 800 without deviating from the scope of the present disclosure.

FIGS. 16-17 depict an example power semiconductor device package 800 having example bond structures 620, 630 for purposes of illustration and discussion. Those having ordinary skill in the art, using the disclosures provided herein, will understand that example power semiconductor device packages of the present disclosure may include different bond structures having different shapes, sizes, arrangements, configurations, etc. without deviating from the scope of the present disclosure.

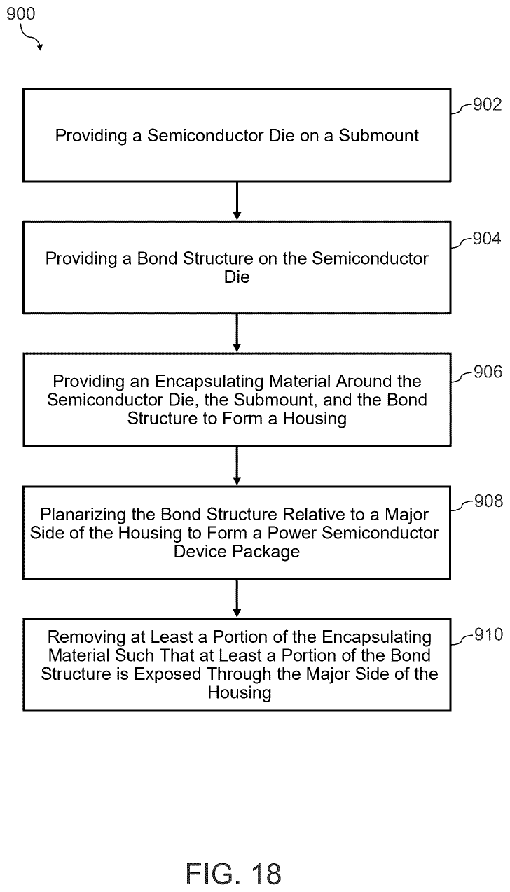

FIG. 18 depicts a flow chart diagram of an example method 900 according to example embodiments of the present disclosure. FIG. 18 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 902, the method 900 includes providing a semiconductor die on a submount. In some examples, the semiconductor die may include a metal-oxide-semiconductor field-effect transistor (MOSFET). In some examples, the semiconductor die may include a Schottky diode. Those having ordinary skill in the art, using the disclosures provided herein, will understand that a semiconductor die of the present disclosure may include any suitable semiconductor device without deviating from the scope of the present disclosure.

At 904, the method 900 includes providing a bond structure on the semiconductor die. More particularly, the bond structure may be ultrasonically bonded to the semiconductor die. In some examples, the bond structure may be coupled to at least one metal contact of the semiconductor die. Additionally and/or alternatively, in some examples, the bond structure may be coupled to a non-metal region of the semiconductor die. Furthermore, in some examples, the bond structure may be coupled to at least one electrical lead of a plurality of electrical leads that may be coupled to the semiconductor die. Additionally and/or alternatively, in other examples, the bond structure may not be electrically coupled to any of the plurality of electrical leads that may be coupled to the semiconductor die.

In some examples, a first bond structure and a second bond structure may be provided on the semiconductor die. The second bond structure may be spaced apart from the first bond structure. In such examples, the first bond structure may be configured to provide a first heat dissipation path through a side of semiconductor die, and the second bond structure may be configured to provide a second heat dissipation path through the side of the semiconductor die that is different from the first heat dissipation path. Hence, the second bond structure may be a different bond structure relative to the first bond structure.

Additionally and/or alternatively, in some examples, the bond structure may be provided on a first side (e.g., top side) of the semiconductor die, and a conductive structure may be provided on a second side (e.g., bottom side) of the semiconductor die that is opposite the first side. In such examples, the bond structure may be configured to provide a first heat dissipation path through the first side of the semiconductor die, and the conductive structure may be configured to provide a second heat dissipation path through the second side of the semiconductor die.

At 906, the method 900 includes providing an encapsulating material around the semiconductor die, the submount, and the bond structure to form a housing.

At 908, the method 900 includes planarizing the bond structure relative to a major side of the housing to form a power semiconductor device package. More particularly, to planarize the bond structure, the method 900 may include applying a compressive force to the bond structure to induce a plastic deformation in the bond structure such that at least a portion of the bond structure is co-planar with the major side of the housing. As one non-limiting example, at least a portion of the bond structure may be planarized by a mold structure (e.g., mold chase) during fabrication of the power semiconductor device package. However, those having ordinary skill in the art, using the disclosures provided herein, will understand that the bond structure may be planarized using any suitable method, process, structure, etc. without deviating from the scope of the present disclosure.

At 910, the method 900 may include removing at least a portion of the encapsulating material such that at least a portion of the bond structure is exposed through the side of the housing (e.g., major side of the housing). More particularly, subsequent to planarizing the bond structure at 908, the method 900 may include removing at least a portion of the encapsulating material (e.g., provided at 906) that forms the major side of the housing such that at least a portion of the bond structure is exposed through the side of the housing. The portion of the encapsulating material may be removed using any suitable removal method, such as, by way of non-limiting example, cutting, grinding, blasting, brushing, trimming, and/or the like. In this way, the bond structure may be configured to provide a heat dissipation path through the side of the housing (e.g., via the exposed portion of the bond structure). Furthermore, in some examples, the method 900 may further include anodizing at least the portion of the bond structure that is exposed through the side of the housing, thereby electrically isolating at least the portion of the bond structure that is exposed through the side of the housing from the semiconductor die.

Example aspects of the present disclosure are set forth below. Any of the below features or examples may be used in combination with any of the embodiments or features provided in the present disclosure.

One example aspect of the present disclosure is directed to a power semiconductor device package. The power semiconductor device package includes a housing, a submount, a semiconductor die on the submount, and a malleable bond structure at least partially exposed through a side of the housing. The malleable bond structure is configured to provide a heat dissipation path through the side of the housing.

In some examples, the malleable bond structure is ultrasonically bonded to the semiconductor die.

In some examples, the malleable bond structure is coupled to at least one metal contact of the semiconductor die.

In some examples, the malleable bond structure is coupled to a non-metal region of the semiconductor die.

In some examples, an exposed portion of the malleable bond structure is co-planar with the side of the housing.

In some examples, the exposed portion of the malleable bond structure is co-planar with a top side of the housing.

In some examples, a shape of the malleable bond structure is planarized by a mold structure during fabrication of the power semiconductor device package.

In some examples, the shape of the malleable bond structure is planarized relative to the side of the housing based on a compressive force applied by the mold structure that induces a plastic deformation of the malleable bond structure.

In some examples, the malleable bond structure includes at least one of aluminum (Al) or copper (Cu).

In some examples, the malleable bond structure includes aluminum (Al).

In some examples, the malleable bond structure includes copper (Cu).

In some examples, the malleable bond structure includes one of copper-clad aluminum (CCA) or aluminum-clad copper (ACC).

In some examples, the malleable bond structure has a thickness in a range of about 50 microns to about 1000 microns.

In some examples, the malleable bond structure includes one or more wire bonds.

In some examples, the malleable bond structure includes a plurality of adjacent wire bonds.

In some examples, each wire bond includes a height and a width, and a height-to-width ratio of each wire bond is about 1:1.

In some examples, the malleable bond structure includes one or more ribbon bonds.

In some examples, each ribbon bond includes a height and a width, and a height-to-width ratio of each ribbon bond is less than 1:1.

In some examples, the malleable bond structure includes a rectangular cross-section.

In some examples, the malleable bond structure includes a circular cross-section.

In some examples, the semiconductor die includes a metal-oxide-semiconductor field-effect transistor (MOSFET).

In some examples, the malleable bond structure is coupled to a source contact of the semiconductor die.

In some examples, the malleable bond structure is a first malleable bond structure, and the power semiconductor device package further includes a second malleable bond structure spaced apart from the first malleable bond structure and at least partially exposed through the side of the housing, the second malleable bond structure configured to provide a separate heat dissipation path through the side of the housing relative to the first malleable bond structure.

In some examples, the second malleable bond structure is coupled to a gate contact of the semiconductor die.

In some examples, the semiconductor die includes a Schottky diode.

In some examples, the power semiconductor device package further includes a plurality of electrical leads extending from the housing.

In some examples, the malleable bond structure is coupled to at least one of the plurality of electrical leads.

In some examples, the malleable bond structure is not electrically coupled to any of the plurality of electrical leads.

In some examples, the malleable bond structure is configured to provide a first heat dissipation path through a first major side of the housing, and the power semiconductor device package further includes a conductive structure on a second major side of the housing that is opposite the first major side, the conductive structure configured to provide a second heat dissipation path through the second major side of the housing, the second heat dissipation path being different from the first heat dissipation path.

In some examples, the conductive structure is coupled to a drain of the semiconductor die.

In some examples, the first major side is a top side of the housing, and the second major side is a bottom side of the housing.

In some examples, the malleable bond structure includes an anodized surface layer.

In some examples, an exposed portion of the malleable bond structure is electrically isolated from the semiconductor die.

Another example aspect of the present disclosure is directed to a power semiconductor device package. The power semiconductor device package includes a housing, a submount, a semiconductor die on the submount, and a malleable bond structure coupled to the semiconductor die. At least a portion of the malleable bond structure is co-planar with a major side of the housing.

In some examples, the malleable bond structure is ultrasonically bonded to the semiconductor die.

In some examples, the malleable bond structure is coupled to at least one metal contact of the semiconductor die.

In some examples, the malleable bond structure is coupled to a non-metal region of the semiconductor die.

In some examples, the portion of the malleable bond structure that is co-planar with the major side of the housing is at least partially exposed through the major side of the housing.

In some examples, the malleable bond structure is configured to provide a heat dissipation path through the major side of the housing.

In some examples, the heat dissipation path is a first heat dissipation path, and the major side of the housing is a first major side of the housing. The power semiconductor device package further includes a conductive structure on a second major side of the housing that is opposite the first major side, the conductive structure configured to provide a second heat dissipation path through the second major side of the housing, the second heat dissipation path being different from the first heat dissipation path.

In some examples, the conductive structure is coupled to a drain of the semiconductor die.

In some examples, the first major side is a top side of the housing, and the second major side is a bottom side of the housing.

In some examples, a shape of the malleable bond structure is planarized by a mold structure during fabrication of the power semiconductor device package.

In some examples, the shape of the malleable bond structure is planarized relative to the major side of the housing based on a compressive force applied by the mold structure that induces a plastic deformation of the malleable bond structure.

In some examples, the malleable bond structure includes at least one of aluminum (Al) or copper (Cu).

In some examples, the malleable bond structure includes aluminum (Al).

In some examples, the malleable bond structure includes copper (Cu).

In some examples, the malleable bond structure includes one of copper-clad aluminum (CCA) or aluminum-clad copper (ACC).

In some examples, the malleable bond structure has a thickness in a range of about 50 microns to about 1000 microns.

In some examples, the malleable bond structure includes one or more wire bonds.

In some examples, the malleable bond structure includes a plurality of adjacent wire bonds.

In some examples, each wire bond includes a height and a width, and a height-to-width ratio of each wire bond is about 1:1.

In some examples, the malleable bond structure includes one or more ribbon bonds.

In some examples, each ribbon bond includes a height and a width, and a height-to-width ratio of each ribbon bond is less than 1:1.

In some examples, the malleable bond structure includes a rectangular cross-section.

In some examples, the malleable bond structure includes a circular cross-section.

In some examples, the malleable bond structure is a first malleable bond structure, and the power semiconductor device package further includes a second malleable bond structure spaced apart from the first malleable bond structure, at least a portion of the second malleable bond structure being co-planar with the major side of the housing.

In some examples, the first malleable bond structure is configured to provide a first heat dissipation path through the major side of the housing, and the second malleable bond structure is configured to provide a second heat dissipation path through the major side of the housing, the second heat dissipation path being different from the first heat dissipation path.

In some examples, the semiconductor die includes a metal-oxide-semiconductor field-effect transistor (MOSFET).

In some examples, the malleable bond structure is coupled to a source contact of the semiconductor die.

In some examples, the malleable bond structure is coupled to a gate contact of the semiconductor die.

In some examples, the semiconductor die includes a Schottky diode.

In some examples, the power semiconductor device package further includes a plurality of electrical leads extending from the housing.

In some examples, the malleable bond structure is coupled to at least one of the plurality of electrical leads.

In some examples, the malleable bond structure is not electrically coupled to any of the plurality of electrical leads.

In some examples, the malleable bond structure includes an anodized surface layer.

In some examples, the portion of the malleable bond structure that is co-planar with the major side of the housing is electrically isolated from the semiconductor die.

Another example aspect of the present disclosure is directed to a method. The method includes providing a semiconductor die on a submount. The method further includes providing a bond structure on the semiconductor die. The method further includes providing an encapsulating material around the semiconductor die, the submount, and the bond structure to form a housing. The method further includes planarizing the bond structure relative to a major side of the housing to form a power semiconductor device package.

In some examples, planarizing the bond structure relative to the major side of the housing includes planarizing, with a mold structure, the bond structure relative to the major side of the housing to form the power semiconductor device package.

In some examples, the method further includes removing at least a portion of the encapsulating material such that at least a portion of the bond structure is exposed through the major side of the housing.

In some examples, the method further includes anodizing at least the portion of the bond structure that is exposed through the major side of the housing.

In some examples, at least the portion of the bond structure that is exposed through the major side of the housing is electrically isolated from the semiconductor die.

In some examples, planarizing the bond structure includes applying a compressive force to the bond structure to induce a plastic deformation of the bond structure such that at least a portion of the bond structure is co-planar with the major side of the housing.

In some examples, providing the bond structure on the semiconductor die includes ultrasonically bonding the bond structure to the semiconductor die.

In some examples, providing the bond structure on the semiconductor die includes coupling the bond structure to at least one metal contact of the semiconductor die.

In some examples, providing the bond structure on the semiconductor die includes coupling the bond structure to a non-metal region of the semiconductor die.

In some examples, providing the bond structure on the semiconductor die includes providing a first bond structure on the semiconductor die and providing a second bond structure on the semiconductor die that is different from the first bond structure, the second bond structure being spaced apart from the first bond structure.

In some examples, planarizing the bond structure includes planarizing the first bond structure and the second bond structure relative to the major side of the housing to form the power semiconductor device package.

In some examples, the first bond structure is configured to provide a first heat dissipation path through the major side of the housing, and the second bond structure is configured to provide a second heat dissipation path through the major side of the housing, the second heat dissipation path being different from the first heat dissipation path.

In some examples, the major side of the housing is a first major side. In some examples, providing the bond structure includes providing the bond structure on a first side of the semiconductor die, the bond structure configured to provide a first heat dissipation path through the first major side of the housing, and providing a conductive structure on a second side of the semiconductor die that is opposite the first side, the conductive structure configured to provide a second heat dissipation path through a second major side of the housing that is opposite the first major side.

In some examples, the first major side is a top side of the housing, and the second major side is a bottom side of the housing.

In some examples, the power semiconductor device package includes a plurality of electrical leads extending from a perpendicular side of the housing relative to the major side.

In some examples, providing the bond structure on the semiconductor die further includes coupling the bond structure to at least one of the plurality of electrical leads.

In some examples, providing the bond structure on the semiconductor die further includes coupling the bond structure to the semiconductor die such that the bond structure is not electrically coupled to any of the plurality of electrical leads.

In some examples, the major side of the housing is a top side of the housing.

In some examples, the bond structure is a malleable bond structure.

In some examples, the semiconductor die includes one of a metal-oxide-semiconductor field-effect transistor (MOSFET) or a Schottky diode.

In some examples, the bond structure includes at least one of aluminum (Al) or copper (Cu).

In some examples, the bond structure includes aluminum (Al).

In some examples, the bond structure includes copper (Cu).

In some examples, the bond structure includes one of copper-clad aluminum (CCA) or aluminum-clad copper (ACC).

In some examples, the bond structure has a thickness in a range of about 50 microns to about 1000 microns.

In some examples, the bond structure includes one or more wire bonds.

In some examples, the bond structure includes a plurality of adjacent wire bonds.

In some examples, each wire bond includes a height and a width, and a height-to-width ratio of each wire bond is about 1:1.

In some examples, the bond structure includes one or more ribbon bonds.

In some examples, each ribbon bond includes a height and a width, and a height-to-width ratio of each ribbon bond is less than 1:1.

In some examples, the bond structure includes a rectangular cross-section.

In some examples, the bond structure includes a circular cross-section.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor device package, comprising:
a housing;
a submount;
a semiconductor die on the submount; and
a malleable bond structure at least partially exposed through a side of the housing, the malleable bond structure configured to provide a heat dissipation path through the side of the housing.

2. The power semiconductor device package of claim 1, wherein the malleable bond structure is ultrasonically bonded to the semiconductor die.

3. The power semiconductor device package of claim 1, wherein an exposed portion of the malleable bond structure is co-planar with the side of the housing.

4. The power semiconductor device package of claim 3, wherein a shape of the malleable bond structure is planarized by a mold structure during fabrication of the power semiconductor device package.

5. The power semiconductor device package of claim 4, wherein the shape of the malleable bond structure is planarized relative to the side of the housing based on a compressive force applied by the mold structure that induces a plastic deformation of the malleable bond structure.

6. The power semiconductor device package of claim 1, wherein the malleable bond structure comprises at least one of:
aluminum (Al); or
copper (Cu).

7. The power semiconductor device package of claim 6, wherein the malleable bond structure comprises one of:
copper-clad aluminum (CCA); or
aluminum-clad copper (ACC).

8. The power semiconductor device package of claim 1, wherein the malleable bond structure comprises one or more wire bonds.

9. The power semiconductor device package of claim 1, wherein the malleable bond structure comprises one or more ribbon bonds.

10. The power semiconductor device package of claim 1, wherein the semiconductor die comprises a metal-oxide-semiconductor field-effect transistor (MOSFET).

11. The power semiconductor device package of claim 10, wherein the malleable bond structure is coupled to a source contact of the semiconductor die.

12. The power semiconductor device package of claim 11, wherein the malleable bond structure is a first malleable bond structure, the power semiconductor device package further comprising:
a second malleable bond structure spaced apart from the first malleable bond structure and at least partially exposed through the side of the housing, the second malleable bond structure configured to provide a separate heat dissipation path through the side of the housing relative to the first malleable bond structure.

13. The power semiconductor device package of claim 12, wherein the second malleable bond structure is coupled to a gate contact of the semiconductor die.

14. The power semiconductor device package of claim 1, wherein the semiconductor die comprises a Schottky diode.

15. The power semiconductor device package of claim 1, further comprising a plurality of electrical leads extending from the housing.

16. The power semiconductor device package of claim 15, wherein the malleable bond structure is coupled to at least one of the plurality of electrical leads.

17. The power semiconductor device package of claim 15, wherein the malleable bond structure is not electrically coupled to any of the plurality of electrical leads.

18. The power semiconductor device package of claim 1, wherein the malleable bond structure is configured to provide a first heat dissipation path through a first major side of the housing, the power semiconductor device package further comprising:
a conductive structure on a second major side of the housing that is opposite the first major side, the conductive structure configured to provide a second heat dissipation path through the second major side of the housing, the second heat dissipation path being different from the first heat dissipation path.

19. A power semiconductor device package, comprising:
a housing;
a submount;
a semiconductor die on the submount; and
a malleable bond structure coupled to the semiconductor die, at least a portion of the malleable bond structure being co-planar with a major side of the housing.

20. A method, comprising:
providing a semiconductor die on a submount;
providing a bond structure on the semiconductor die;
providing an encapsulating material around the semiconductor die, the submount, and the bond structure to form a housing; and
planarizing the bond structure relative to a major side of the housing to form a power semiconductor device package.
